(19) United States
(12) Patent Application Publication
(10) Pub. No.: US 2014/0197463 A1
(43) Pub. Date: Jul. 17, 2014

(54) METAL-PROGRAMMABLE INTEGRATED CIRCUITS

(71) Applicant: Altera Corporation, (US)

(72) Inventors: Chong Gim Gan, Gelugor (MY); Hee Kong Phoon, Bagan Serai (MY); Sean Woei Voon, Bukit Mertajam (MY)

(73) Assignee: Altera Corporation, San Jose, CA (US)

(21) Appl. No.: 13/742,044

(22) Filed: Jan. 15, 2013

(51) Int. Cl. H01L 27/088; H01L 29/66

(52) U.S. Cl. CPC H01L 27/0886; H01L 29/66795
USPC 257/204; 438/128

(57) ABSTRACT

A metal-programmable integrated circuit may include an array of metal-programmable cells. Each cell may include multi-gate transistor structures in which multiple surfaces of a gate structure serve to control current flow through at least one channel structure. The multi-gate transistor structures may form one or more fin-shaped field effect transistors. The gate structure may at least partially enclose multiple channel structures. Pairs of source-drain structures may be coupled to the channel structures. The transistor structures of each cell may be formed in a substrate covered with one or more metal interconnect layers. Paths formed in the metal interconnect layers may configure the cells to perform desired logic functions. The paths associated with a given cell may be selectively coupled to transistor structures of the cell to configure the cell for a desired logic function and/or for desired output drive strength.

### BACKGROUND

Integrated circuits are often designed to perform desired functions. During manufacturing, a mask is typically used to produce circuitry on the integrated circuit (e.g., using photolithography and other manufacturing techniques). Circuitry on an application-specific integrated circuit (ASIC) is formed using specialized masks that are generated for producing specific circuit structures. The specialized ASIC masks may be used to generate multiple identical integrated circuits, which tends to reduce the overall cost. For example, hundreds, thousands, millions, or more integrated circuits may be manufactured using the specialized masks. However, a specialized ASIC mask is expensive and is only capable of producing identical integrated circuits.

Metal-programmable gate arrays can help to reduce manufacturing costs. Different cells of the metal-programmable gate arrays are interconnected to form circuits that perform logic functions. Each cell of the metal-programmable gate array has circuit attributes such as drive strength that are predetermined and fixed. Such cell structures can lead to inefficient use of integrated circuit resources due to mismatch between desired circuit attributes and fixed cell attributes.

### SUMMARY

A metal-programmable integrated circuit may include an array of metal-programmable cells. Each cell may be formed with identical transistor structures that form a base layer of the metal-programmable integrated circuit. The transistor structures of each cell may be formed from multi-gate transistor structures in which multiple surfaces of a gate structure serve to control current flow through at least one channel structure. The multi-gate transistor structures may form one or more fin-shaped field effect transistors (FinFETs). The gate structure may at least partially enclose multiple channel structures that serve as fins of a FinFET transistor. Pairs of source-drain structures may be coupled to the channel structures. If desired, multiple gate structures may share some of the source-drain structures.

The transistor structures of each cell may be formed in a substrate. One or more metal interconnect layers may cover the substrate. Paths formed in the metal interconnect layers may configure the cells to perform desired logic functions. The paths associated with a given cell may be selectively coupled to transistor structures of the cell such as the gate and source-drain structures to configure the cell for a desired logic function and/or for desired output drive strength.

The transistor structures of the array of metal-programmable cells may be formed using a base layer mask. The array of metal-programmable cells may be subsequently configured to perform logic functions of a custom logic design. The array of metal-programmable cells may be configured by using a metal layer mask to form appropriate paths in the metal interconnect layers.

Further features of the present invention, its nature and various advantages will be more apparent from the accompanying drawings and the following detailed description.

### BRIEF DESCRIPTION OF THE DRAWINGS

FIG. 1 is a diagram of an illustrative metal-programmable integrated circuit in accordance with an embodiment of the present invention.

FIG. 2 is a cross-sectional view of an illustrative metal-programmable integrated circuit in accordance with an embodiment of the present invention.

FIG. 3 is a perspective view of illustrative multi-gate transistor structures of metal-programmable integrated circuit in accordance with an embodiment of the present invention.

FIG. 4 is a layout diagram of illustrative multi-gate transistor structures having a single gate structure in accordance with an embodiment of the present invention.

FIG. 5 is a layout diagram of illustrative multi-gate transistor structures having multiple gate structures with shared source-drain structures in accordance with an embodiment of the present invention.

FIG. 6 is a layout diagram of illustrative multi-gate transistor structures that have been metal-programmed in accordance with an embodiment of the present invention.

FIG. 7 is an illustrative circuit diagram of the metal-programmed transistor structures of FIG. 6 in accordance with an embodiment of the present invention.

FIG. 8 is a layout diagram of an illustrative metal-programmable cell configured as an inverter with unit output drive strength in accordance with an embodiment of the present invention.

FIG. 9 is an illustrative circuit diagram of the metal-programmable cell configured as an inverter with unit output drive strength of FIG. 8 in accordance with an embodiment of the present invention.

FIG. 10 is a layout diagram of an illustrative metal-programmable cell configured as an inverter with increased output drive strength in accordance with an embodiment of the present invention.

FIG. 11 is an illustrative circuit diagram of the metal-programmable cell configured as an inverter with increased output drive strength of FIG. 10 in accordance with an embodiment of the present invention.

FIG. 12 is a layout diagram of an illustrative metal-programmable cell configured as an inverter with reduced output drive strength in accordance with an embodiment of the present invention.

FIG. 13 is an illustrative circuit diagram of the metal-programmable cell configured as an inverter with reduced output drive strength of FIG. 8 in accordance with an embodiment of the present invention.

FIG. 14 is a layout diagram of an illustrative metal-programmable cell configured as a logic NOR gate in accordance with an embodiment of the present invention.

FIG. 15 is an illustrative circuit diagram of the metal-programmable cell configured as a logic NOR gate of FIG. 14 in accordance with an embodiment of the present invention.

FIG. 16 is a layout diagram of an illustrative metal-programmable cell configured as a logic NAND gate in accordance with an embodiment of the present invention.

FIG. 17 is an illustrative circuit diagram of the metal-programmable cell configured as a logic NAND gate of FIG. 16 in accordance with an embodiment of the present invention.

FIG. 18 is a layout diagram of an illustrative metal-programmable cell configured as a signal bus in accordance with an embodiment of the present invention.

FIG. 19 is an illustrative circuit diagram of the metal-programmable cell configured as a signal bus of FIG. 18 in accordance with an embodiment of the present invention.

FIG. 20 is a diagram of illustrative steps that may be performed to manufacture and configure a metal-programmable integrated circuit in accordance with an embodiment of the present invention.

FIG. 21 is a flow chart of illustrative steps that may be performed to manufacture and configure a metal-programmable integrated circuit in accordance with an embodiment of the present invention.

### DETAILED DESCRIPTION

Embodiments of the present invention relate to integrated circuits containing metal-programmable cells (sometimes referred to herein as metal-programmable integrated circuits) and methods of manufacturing such circuits.

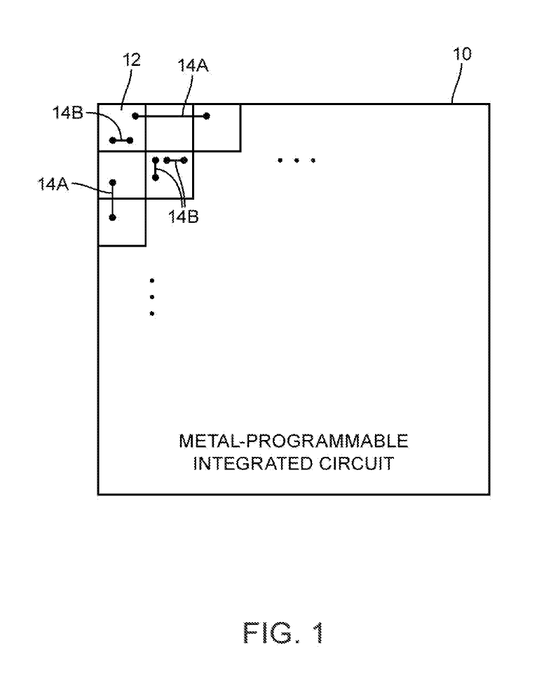

FIG. 1 shows a diagram of an illustrative metal-programmable integrated circuit device. Metal-programmable integrated circuit 10 may include metal-programmable cells 12 that are arranged in a repeating cell structure. Cells 12 may include transistor structures formed on an integrated circuit substrate using a base layer mask (e.g., using photolithography and associated etching processes that produce circuit structures as defined by the base layer mask). Interconnects 14A and 14B may serve to configure the metal-programmable integrated circuit for desired functionality. Interconnects 14A and 14B may be formed using one or more metal layer masks to pattern metal interconnect layers that cover the substrate. Interconnects 14A may couple two or more different cells, whereas interconnects 14B may provide electrical paths within a given cell. The example of FIG. 1 is merely illustrative. In general, any desired interconnect structures may be formed using metal layer masks (e.g., conductive lines, vias, etc.).

Metal-programmable integrated circuit 10 may be configured to implement any desired circuit functionality. For example, groups of cells 12 may be programmed using a metal layer mask to implement input-output (I/O) circuitry for driving signals off of device 10 and for receiving signals from other devices via input-output pins (not shown). As another example, groups of cells 12 may be programmed to implement processing circuitry, storage circuitry (e.g., memory circuits such as static random access memory circuits), logic circuits, or any desired circuitry.

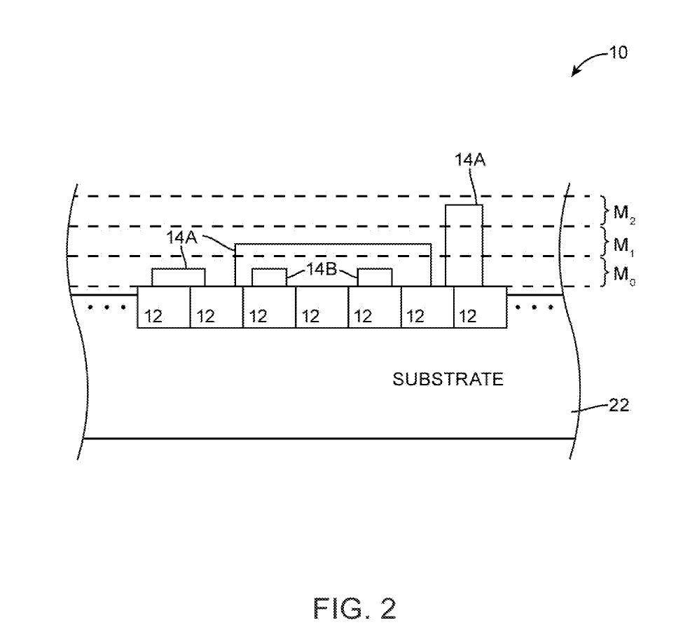

FIG. 2 is a cross-sectional view of an illustrative metal-programmable integrated circuit 10. As shown in FIG. 2, cells 12 may be formed within integrated circuit substrate 22. Substrate 22 may be formed from silicon or any other desired substrate material. Metal layers may cover cells 12 and substrate 22. In the example of FIG. 2, metal-programmable integrated circuit 10 includes metal interconnect layers M0, M1, and M2. In general, circuit 10 may be formed with any desired number of metal interconnect layers (e.g., one, two, three, four, five, or more). The metal layers may be formed from copper, aluminum, or any desired metal or conductive materials. Interconnects 14A and 14B may be formed at any desired metal layer or may include portions formed within multiple metal layers.

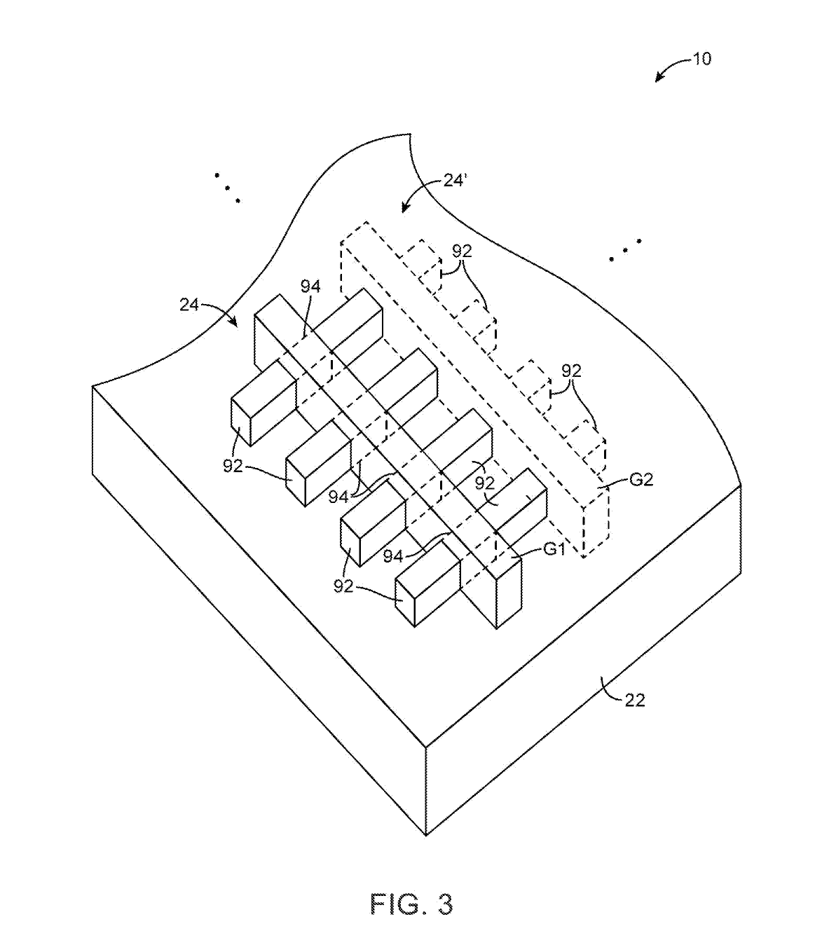

Cells 12 may include transistor structures that are metal-programmable. For example, the functionality and drive strength of the transistor structures of each cell 12 may be programmed using metal layer interconnects 14B. Metal-programmable transistors may include multi-gate transistors. Multi-gate transistors may be formed with gate structures that cover multiple surfaces of corresponding channel structures. In this scenario, each covered surface may function as a gate terminal of the multi-gate transistor. The gate terminals may be shorted for more effective control over current flow through the channel structure. For example, multi-gate transistors may include Fin-Shaped Field Effect Transistors (FinFETs). FIG. 3 is a perspective view of illustrative metal-programmable transistor structures 24 of device 10.

As shown in FIG. 3, metal-programmable transistor 24 may include gate structure G1 that surrounds and partially encloses multiple channel structures 94 (e.g., gate structure G1 may cover multiple surfaces of each channel structure 94). Gate structures such as structure G1 may be formed from conductive materials such as polysilicon, metals, metal alloys, metal composites, etc. Each channel structure 94 may be coupled to respective pair of source-drain structures 92. The source-drain structures may be formed from vertical extensions of substrate 22 or may be formed separately from substrate 22. The source-drain structures may be formed from doped semiconductor materials such as doped silicon (e.g., N-type or P-type). A layer of insulator (not shown) such as silicon dioxide or other insulators such as high-K insulators may be interposed between channel structures 94 and gate structure G1.

Source-drain regions 92 may be formed from doped silicon (e.g., n-type or p-type doped silicon) or other doped semiconductor materials such as doped Germanium. Transistor structures 24 may be activated by applying an appropriate voltage (e.g., exceeding a threshold voltage) to gate G1, which enables current flow through channels 94. If desired, multiple gate structures may be formed. For example, optional gate structure G2 that partially encloses respective channel structures 94 (not shown) may be provided. Optional gate structure G2 may share center source-drain regions 92 with gate structure G1 and may have additional source-drain structures 92 (shown in dashed lines). In general, each gate structure may have a pair of source-drain structures 92 for each channel structure 94. Each pair of source-drain structures 92 and the associated channel structure 94 may form a so-called “fin” that extends through the gate structure.

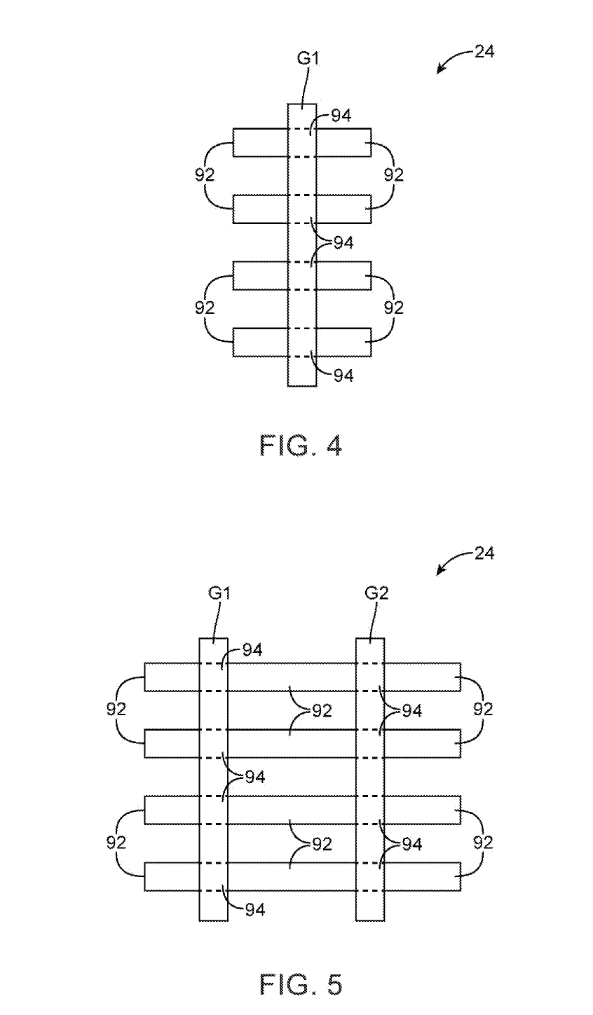

FIG. 4 is a top-down layout view of illustrative transistor structures 24 having a single gate structure G1. Source-drain regions 92 may be coupled to channel structures 94 that extend through gate structure G1. If desired, transistor structures 24 may be provided with multiple gate structures as shown in the layout view of FIG. 5 and described in connection with optional gate structure G1 of FIG. 3.

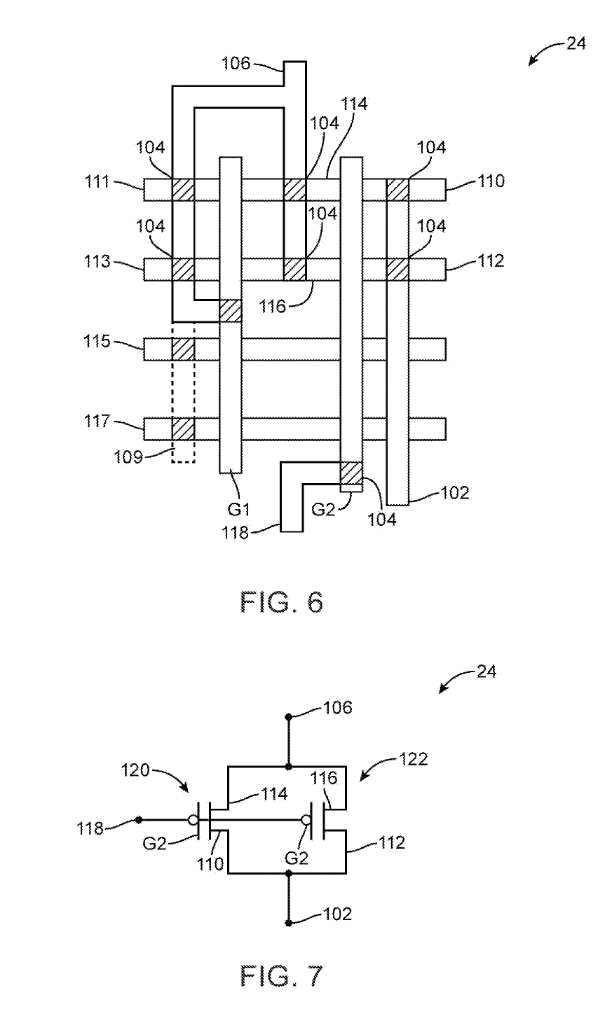

Metal-programmable transistor structures 24 may be configured to perform desired functions by forming interconnects between portions of structures 24. FIG. 6 is a layout view showing how metal-programmable transistor structures 24 of FIG. 5 may be programmed. As shown in FIG. 6, interconnects 102 and 106 may be formed in metal interconnect layers (e.g., metal interconnect layers M0, M1, M2, etc. of FIG. 2). Interconnects 102 and 106 may sometimes be referred to herein as intra-cell interconnects that electrically couple terminals within a cell such as cell 12 of FIG. 1.

Interconnect 102 may be coupled to source-drain structures (terminals) 110 and 112 via connections 104. Connections 104 may include conductive vias that couple metal layers of interconnect 102 to transistor structures. Interconnect 106 may be coupled to source-drain structures 114 and 116 associated with source-drain structures 110 and 112. Source-drain structure 114 may be coupled to structure 110 through gate structure G2, whereas source-drain structure 116 may be coupled to structure 112 via gate structure G2. Gate structure G2 may be coupled to interconnect 118 via a connection 104.

In the example of FIG. 6, gate structure G2 and source-drain regions 110, 112, 114, and 116 may effectively serve as a pair of transistors that are coupled in parallel between terminals associated with interconnects 106 and 102. Gate structure G1 may be unused in the arrangement of FIG. 6. If desired, source-drain regions 111 and 113 associated with gate structure G1 may be electrically shorted to corresponding source-drain regions 114 and 116 via interconnect 106 and connections 104. In this way, transistor structures associated with gate G1 may be deactivated, because the source-drain regions associated with gate G1 may be shorted to each other and to gate G1 (e.g., gate-to-source and source-to-drain voltages may be zero). If desired, conductive path 106 may also be coupled to source-drain regions 115 and 117 via optional extension portion 109, which may help to ensure stable operation of transistor structures 24 (e.g., to avoid floating terminals).

FIG. 7 is an illustrative circuit diagram of transistor structures 24 corresponding to the metal-programmed arrangement of FIG. 6. As shown in FIG. 7, transistors 120 and 122 share gate structures G2 as represented by a shorting path between the gate terminals of transistors 120 and 122. Interconnect 118 serves as an input terminal to gate structures G2.

Source-drain regions 110 and 112 of transistors 120 and 122 may be electrically shorted by interconnect 102, whereas source-drain regions 114 and 116 may be shorted by interconnect 106. Transistors 120 and 122 may effectively form a transistor structure having twice the output drive strength of transistor 120 or 122 individually (e.g., a transistor having twice the width of transistor 120 or 122). Metal-programming using intra-cell interconnects 102 and 106 similar to the arrangement of FIG. 6 may be used to configure transistor structures 24 as a transistor having a drive strength of one times the drive strength of transistor 120, two times the drive strength of transistor 120, or any desired multiple of the drive strength of transistor 120. For example, transistor structures 24 may be programmed to function with four times the drive strength of a single transistor by connecting paths 102 and 106 to two additional pairs of source-drain structures associated with gate structure G2 (e.g., by activating four fins associated with gate structure G2).

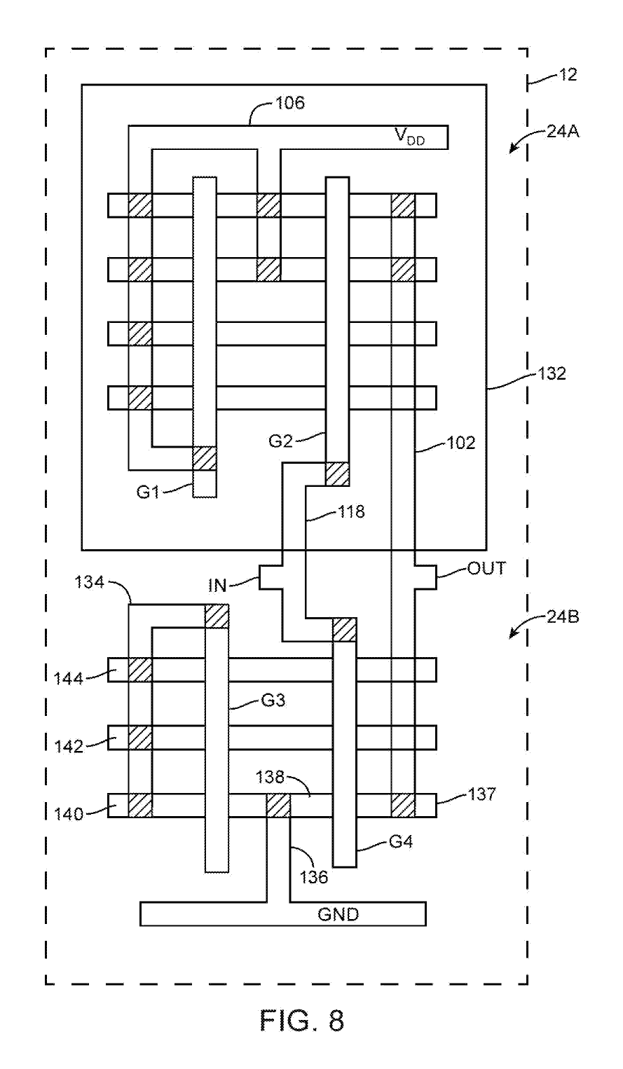

In the example of FIG. 7, transistors 120 and 122 may form P-type transistor structures having channel structures with N-type doping (e.g., channel structures formed from a vertical or upwards extension of an N-type underlying substrate). This example is merely illustrative. If desired, transistors 120 and 122 may be formed as N-type transistors with channel structures having P-type doping. Cells 12 of a metal-programmable integrated circuit may include both P-type and N-type transistor structures. FIG. 8 is an illustrative layout view of a cell 12 including P-type and N-type metal-programmable transistor structures.

As shown in FIG. 8, cell 12 may include P-type transistor structures 24A and N-type transistor structures 24B. The example of FIG. 8 is merely illustrative. If desired, cell 12 may include only P-type transistor structures or only N-type transistor structures. Transistor structures 24A and 24B may each be formed similarly to structures 24 of FIG. 5 (e.g., having multiple gate structures each with multiple channels and source-drain regions). In the example of FIG. 8, transistor structures 24A are formed with four fins that extend through gate structures G1 and G2 and transistor structures 24B are formed with three fins that extend through gate structures G3 and G4. This example is merely illustrative. If desired, transistor structures 24A and 24B may be formed with two fins each, three fins each, a different number of fins each, or any desired number of fins.

Cell 12 may be metal-programmed to function as an inverter by forming interconnects 102, 106, 118, 134, and 136 in metal layers that cover transistor structures 24A and 24B. Interconnects 102, 106, and 118 may be connected to transistor structures 24A similarly to FIG. 6 so that structures 24A are configured to function as a pair of parallel-connected P-type transistors. Positive power supply voltage VDD may be provided via interconnect 106. Power supply ground voltage GND may be provided via path 136. Interconnect 102 may be coupled to source-drain region 137 of transistor structures 24B, whereas interconnect 136 may be coupled to source-drain region 138 that is shared between gate structures G3 and G4. Interconnect 134 may electrically short source-drain regions 140, 142, and 142 to gate conductor G3, which helps ensure that transistor structures associated with gate conductor G3 are disabled. Interconnect 118 may serve as an input terminal at which input signal IN is received, whereas interconnect 102 may serve as an output terminal at which inverted output signal OUT is provided.

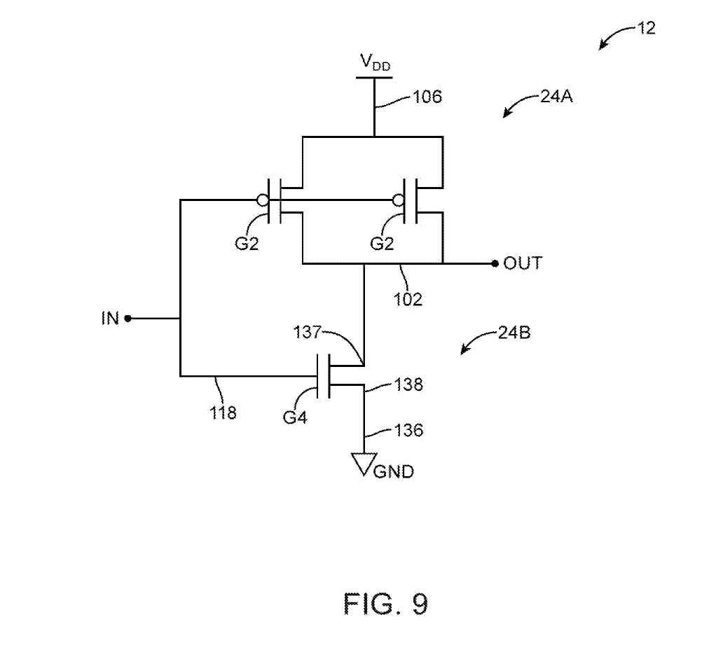

An illustrative circuit diagram of the metal-programmed cell 12 of FIG. 8 is shown in FIG. 9. As shown in FIG. 9, interconnects 102 and 106 configure transistor structures 24A as two P-type transistors coupled in parallel between a positive power supply terminal (path 106) and an output terminal (path 102). Path 102 is coupled to source-drain region 137 of transistor structures 24B and path 136 is coupled to corresponding source-drain region 138 so that transistor structures 24B are configured as an N-type transistor coupled between the output terminal (path 102) and the power supply ground terminal. Path 118 that couples gate structures G2 and G4 serves as an inverter input terminal.

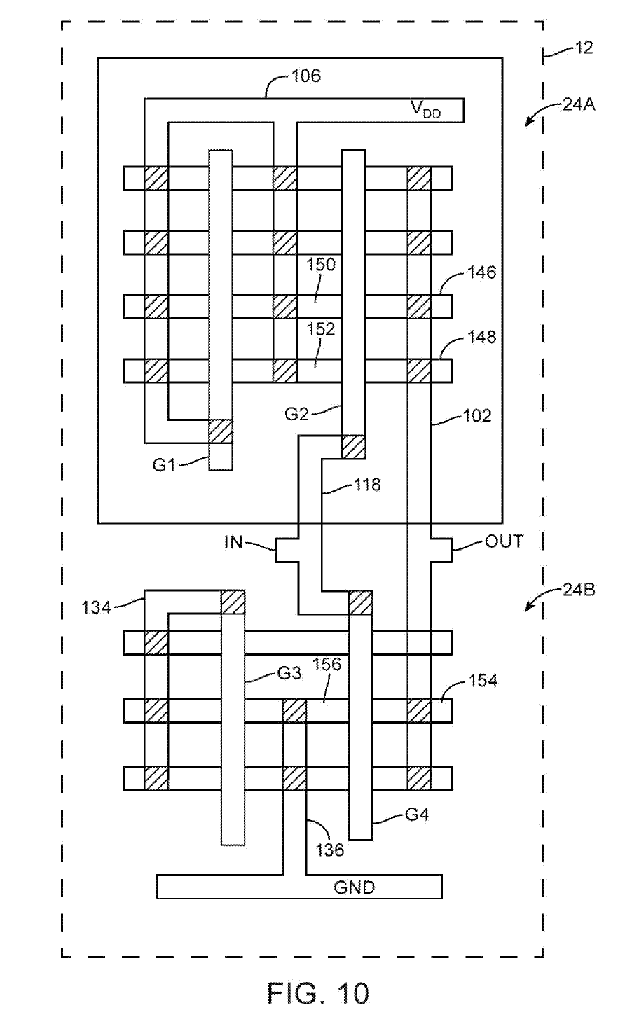

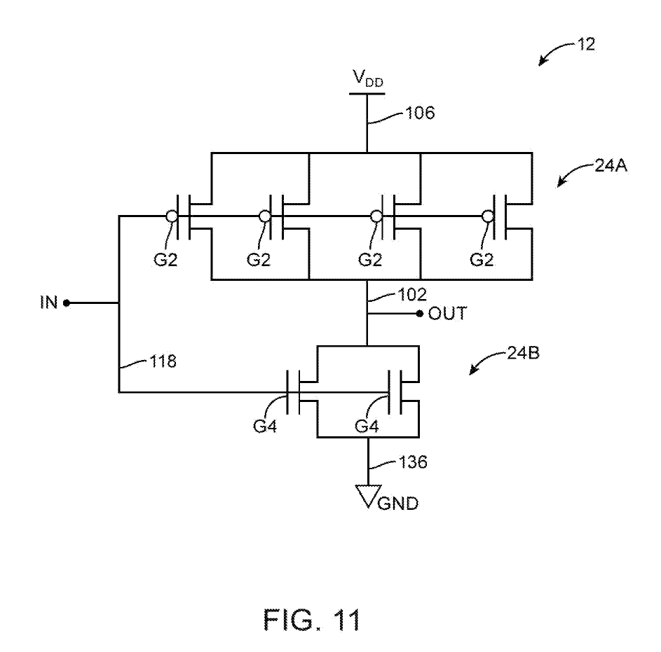

In the example of FIGS. 8 and 9, cell 12 is programmed to function as an inverter with a unit drive strength (sometimes referred to as an X1 inverter). If desired, cell 12 may be configured using metal layers to have any suitable drive strength. FIG. 10 is an illustrative layout view showing how cell 12 may be metal-programmed to serve as an inverter having twice the drive strength of the inverter of FIGS. 8 and 9 (sometimes referred to as an X2 inverter).

As shown in FIG. 10, paths 102, 106, and 136 may each be electrically coupled to twice the number of source-drain regions relative to the X1 inverter of FIG. 8. Path 102 may be coupled to additional source-drain regions 146 and 148 of structures 24A and path 106 may be coupled to additional source drain regions 150 and 152 of structures 24A. Path 102 may be coupled to additional source-drain region 154 of structure 24B and path 136 may be coupled to additional source drain-region 156 of structure 24B.

FIG. 11 is an illustrative circuit diagram of the metal-programmed cell of FIG. 10. As shown in FIG. 11, transistor structures 24A may be configured by paths 102 and 106 to effectively function as four P-type transistors that share gate structures G2 and are coupled in parallel between a positive power supply terminal (path 106) and an output terminal (path 102). Transistor structures 24B may be configured via paths 102 and 136 to effectively function as two N-type transistors that share gate structures G4 and are coupled in parallel between the output terminal and a power supply ground terminal (path 136). Path 118 may be coupled to gate structures G2 and G4 and serve as an input terminal at which input signal IN is received. The metal-programmed cell of FIGS. 10 and 11 may serve as an X2 inverter that drives the output terminal with output signal OUT having twice the drive strength of the inverter of FIGS. 8 and 9.

Cell 12 may be metal-programmed to function as an inverter with non-integer multiple drive strength. If desired, the number of source-drain regions activated via metal layer path connections in transistor structures 24A and 24B may be adjusted to obtain non-integer drive strengths. For example, metal layer path connections to source-drain regions 152 and 148 of FIG. 10 may be omitted to program cell 12 as an inverter with a drive strength between one and two times the unit inverter drive strength.

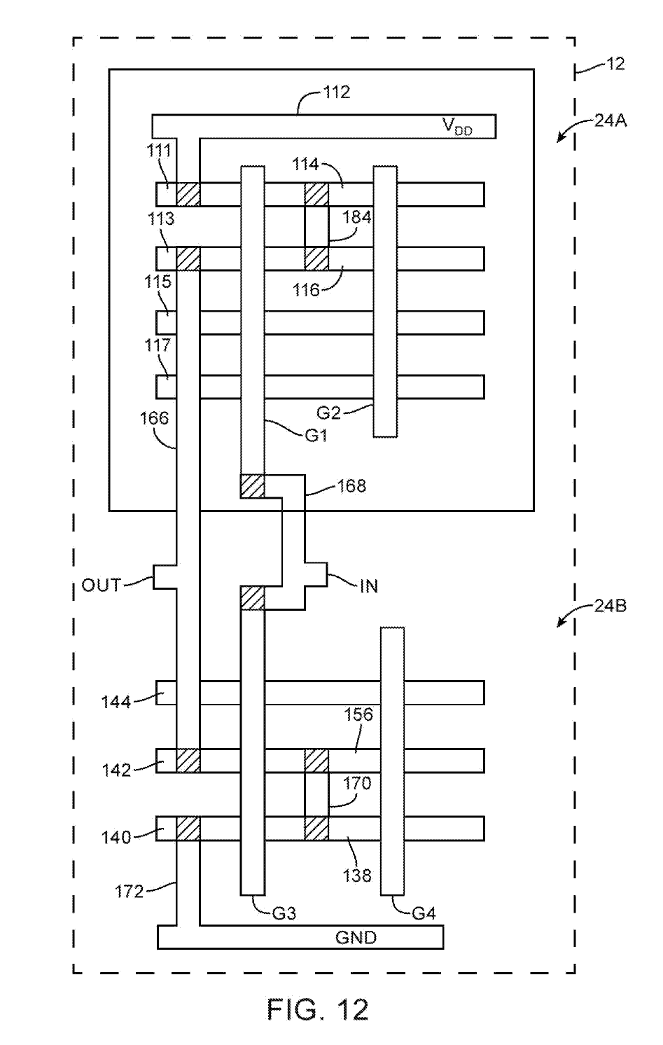

Cell 12 may, if desired, be metal-programmed as an inverter with less than unit drive strength. FIG. 12 is an illustrative layout view of cell 12 that is programmed with less than unit drive strength. As shown in FIG. 12, positive power supply terminal (path 162) may be coupled to source-drain structure 111 of structures 24A. Path 164 may electrically couple corresponding source-drain structure 114 to adjacent source-drain 116 so that structures 24A forms a pair of series connected P-type transistors that share gate structures G1.

Path 166 may be electrically coupled to source-drain structure 113 that is associated with source-drain structure 116. Path 166 may couple source-drain structure 113 of structures 24A to source-drain structure 142 of structures 24B. Source-drain structure 156 associated with structure 142 may be coupled to adjacent source-drain structure 138 via path 170 to form a pair of series connected N-type transistors. Path 172 may be coupled to source-drain structure 140 and may serve as a power supply ground terminal at which power supply ground voltage GND is provided.

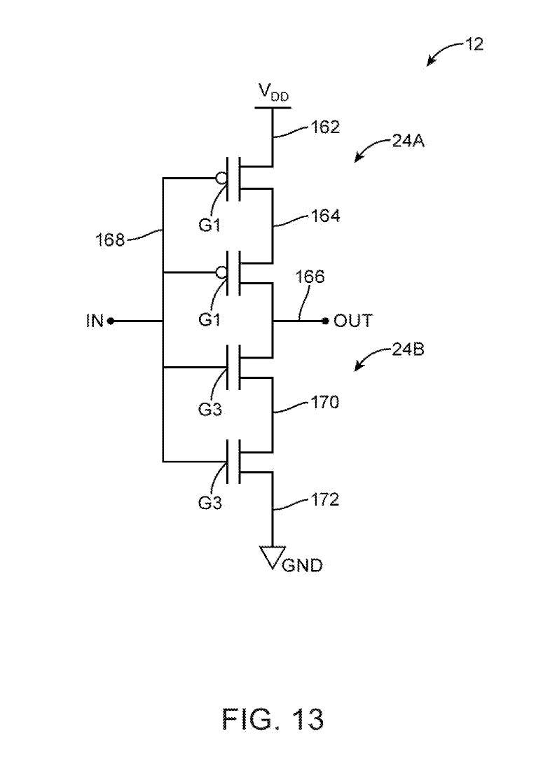

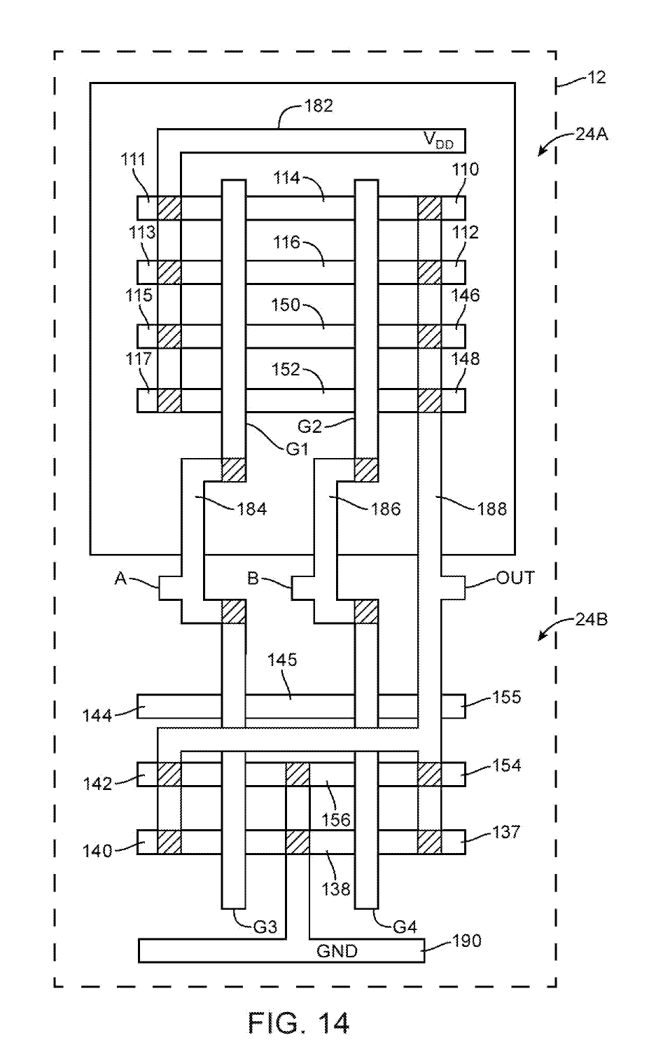

FIG. 13 is an illustrative circuit diagram of the inverter circuit formed from the programmed cell 12 of FIG. 14. As shown in FIG. 13, paths 162, 164, and 166 program structures 24A into a pair of series-connected P-type transistors between a positive power supply terminal and an output terminal. Paths 166, 170, and 172 configure structures 24B as a pair of series-connected N-type transistors between the output terminal and a power supply ground terminal. Gate structures G1 and G3 may be electrically coupled via path 168, which serves as an input terminal for the inverter circuit. The inverter circuit of FIG. 13 may sometimes be referred to as a stacked-transistor inverter circuit, because each type of transistor is stacked in series with an additional transistor of the same type.

The stacked-transistor inverter circuit may drive output signal OUT with a drive strength that is somewhat weaker than the unit inverter drive strength, because the positive power supply voltage is divided across additional source-drain structures. The relatively weak drive strength of the stacked-transistor inverter circuit may be suitable in arrangements such as delay circuits in which increased delay is desirable.

Metal-programmable cell 12 having multiple gate structures with shared source-drain regions may be programmed to form logic gates having multiple inputs. FIG. 14 is an illustrative layout of a cell 12 programmed as a logic NOR gate. The logic NOR gate may receive input signals A and B and produce output signal OUT by performing a logic NOR function on the input signals.

As shown in FIG. 14, path 182 may serve as a positive power supply terminal at which positive power supply voltage VDD is provided. Path 182 may be electrically coupled to source-drain regions 111, 113, 115, and 117 (e.g., source-drain regions 111, 113, 115, and 117 may be shorted to the positive power supply terminal). Path 184 may serve as an input terminal for input signal A and is coupled to gate structures G1 and G3. Path 186 may serve as an input terminal for input signal B and is coupled to gate structures G2 and G4. Path 188 may serve as an output terminal at which output signal OUT is produced by cell 12. Path 188 may be coupled to source-drain regions 110, 112, 146, and 148 of P-type transistor structures 24A. Path 188 may also be coupled to source-drain regions 154, 137, 140, and 142 of N-type transistor structures 24B. Path 190 may serve as a power supply ground terminal at which power supply ground voltage GND is provided. Source-drain regions 138 and 156 of N-type transistor structures 24B may be shorted to the power supply ground terminal via path 190.

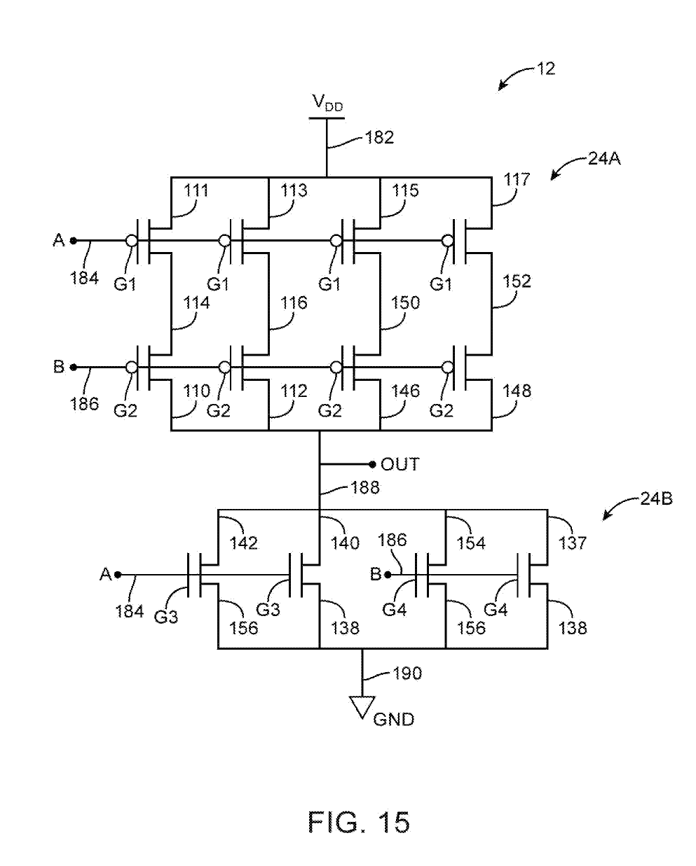

FIG. 15 is an illustrative circuit diagram of cell 12 metal-programmed with the NOR gate configuration of FIG. 14. As shown in FIG. 15, paths 182 and 188 may configure P-type transistor structures to function as four sets of series-connected P-type transistors that are coupled in parallel between a positive power supply terminal and an output terminal.

A first set of series-connected P-type transistors includes two transistors extending from source-drain structures 111 to source-drain structures 114 and 110 across gate structures G1 and G2. In this scenario, the first set of transistors includes a first transistor that receives input signal A at gate structures G1, receives power supply voltage VDD at source-drain structures 111, and is coupled to a second transistor via shared source-drain structures 114. The second transistor receives input signal B at gate structures G2 and is coupled to the output terminal via source-drain structures 110. Similarly, a second set of series-connected P-type transistors includes two transistors extending from source-drain structures 113 to source-drain structures 112 across gate structures G1 and G2, a third set of transistors extends from source-drain structures 115 to source-drain structures 146, and a fourth set of transistors extends from source-drain structures 117 to source-drain structures 148.

During NOR gate operations, the pairs of series-connected P-type transistors serve to drive the output terminal with positive power supply voltage VDD (e.g., logic one) when input signals A and B are both logic zero (e.g., power supply ground voltage GND). The strength at which cell 12 drives output signal OUT with a logic one signal may sometimes be referred to herein as the logic-one driving strength of cell 12. Each pair of series-connected P-type transistors contributes a portion of the logic-one driving strength. The total logic-one driving strength may be programmed by activating a desired number of P-type transistors (e.g., and de-activating the remaining P-type transistors of structures 24A). For example, the logic-one driving strength may be reduced by de-activating one or more pairs of series-connected P-type transistors (e.g., by omitting connections between the metal paths and the source-drain and gate structures of the transistors to be de-activated).

Paths 188 and 190 may program N-type transistor structures 24B as a first pair of parallel-connected N-type transistors controlled by input signal A and a second pair of parallel-connected N-type transistors controlled by input signal B. The first pair of N-type transistors includes a first transistor extending from source-drain structures 142 to source-drain structures 156 across gate structures G3 and a second transistor extending from source-drain structures 140 to source-drain structures 138 across gate structures G3. The first pair of N-type transistors receive input signal A at shared gate structures G3 via path 184. Similarly, the second pair of N-type transistors each receive input signal B via shared gate structures G4 via path 186.

During NOR gate operations, the first and second pairs of parallel-connected N-type transistors serve to drive output signal OUT at logic zero (e.g., power supply ground signal GND). The first pair of N-type transistors that are controlled by input signal A may drive the output signal OUT with logic zero in response to receiving input signal A having a logic one value, whereas the second pair of transistors controlled by input signal B may drive the output signal OUT with logic zero in response to input signal A having a logic one value.

The strength at which output signal OUT is driven with at logic zero may sometimes be referred to herein as the logic-zero driving strength of cell 12. The transistors of structures 24B contribute to the total logic-zero driving strength. Based on the configuration of metal layer paths 188 and 190, the logic-zero driving strength of cell 12 may be adjusted. To increase the logic-zero driving strength, additional transistors of structures 24B may be activated, whereas transistors may be de-activated to reduce the logic-zero driving strength.

As an example, path 188 may be electrically coupled to source-drain structures 144 and path 190 may be electrically coupled to source-drain regions 145 to form an additional transistor in parallel with the first pair of N-type transistors. In this scenario, the logic-zero drive strength associated with input signal A may be increased (e.g., because the additional transistor is controlled by input signal A via gate structures G3 and contributes to the total logic-zero drive strength). Similarly, the logic-zero drive strength associated with input signal B may be increased by coupling path 188 to source-drain structure 155 and path 190 to source-drain structure 145 to form an additional transistor extending from source-drain structure 145 to source-drain structure 155 through gate structures G4.

The logic-zero and logic-one drive strengths of cell 12 may be adjusted independently by configuring the metal layer paths for P-type transistor structures 24A and N-type transistor structures 24B independently. For example, structures 24A may be metal-programmed to have increased drive strength relative to structures 24B, reduced drive strength, or similar drive strength.

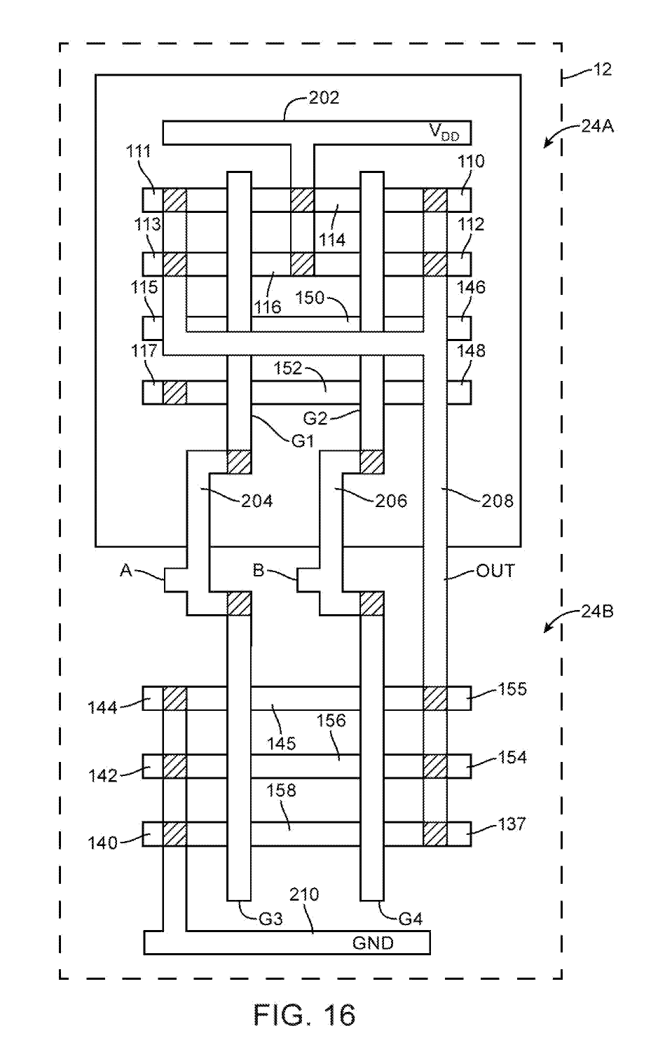

Cell 12 may be metal-programmed to function as any desired logic gate without modifying the base layer of transistor structures (e.g., without modifying transistor structures 24A and 24B that are formed using a base layer mask). FIG. 16 is an illustrative layout of a cell 12 programmed as a logic NAND gate. The NAND gate may receive input signals A and B via paths 204 and 206, respectively. The NAND gate may produce output signal OUT by performing a logic NAND function on input signals A and B.

As shown in FIG. 16, paths 202 and 208 may configure P-type structures 24A as first and second sets of parallel-connected transistors. The first set of parallel-connected transistors may share gate structures G1 and include a first transistor extending from source-drain structure 111 to source-drain structure 114 and a second transistor extending from source-drain structure 113 to source-drain structure 116. The second set of parallel-connected transistors may share gate structures G2 and may include a third transistor extending between source-drain structures 110 and 114 and a fourth transistor extending between source-drain structures 116 and 112.

Paths 208 and 210 may configure N-type structures 24B as multiple pairs of series-connected N-type transistors. Each pair of series-connected transistors includes a first transistor that receives input signal B via gate structures G4 and a second transistor that receives input signal A via gate structures G3. For example, the first pair of series-connected transistors includes a first transistor extending between source-drain structures 145 and 155 and a second transistor extending between source-drain structures 144 and 145. The first and second transistors of each pair may share a source-drain structure (e.g., source-drain structure 145, 156, or 158).

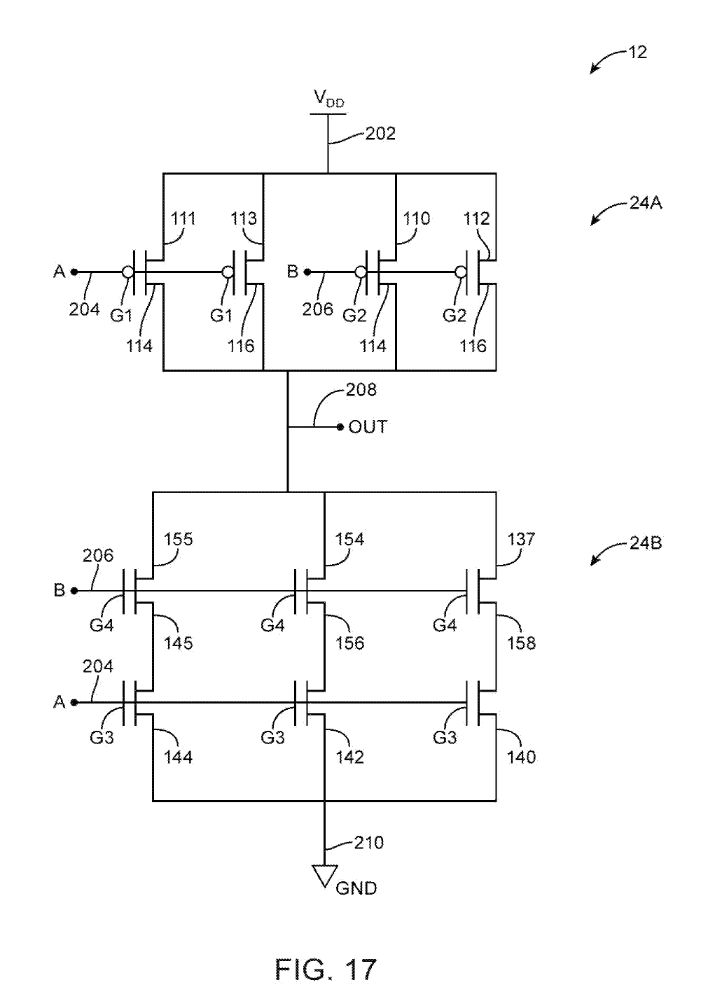

FIG. 17 is an illustrative circuit diagram of the NAND gate configuration shown in FIG. 16. As shown in FIG. 17, P-type structures 24A may serve to drive output signal OUT at logic one, whereas N-type structures 24B may serve to drive output signal OUT at logic zero. The drive strength of each set of parallel-connected transistors of P-type structures 24A may be programmed by coupling paths 202 and 208 to a desired number of source-drain regions (e.g., similarly to adjusting the drive strength of structures 24B as described in connection with FIG. 14). The drive strength of the series-connected transistors of structures 24A may be programmed by coupling paths 208 and 210 to a desired number of source-drain regions (e.g., similarly to adjusting the drive strength of structures 24A as described in connection with FIG. 14).

The examples of FIGS. 14-17 in which cell 12 is metal-programmed as two-input logic circuits (e.g., two-input NOR and NAND gates) are merely illustrative. If desired, cell 12 may be metal-programmed to process any desired number of input signals. For example, each gate structure may receive a different input signal or groups of gate structures may share input signals. Cell 12 may be provided with multiple gate structures (e.g., two, three, four, or more) that can be metal-programmed to receive input signals. Each gate structure may have multiple associated channels and corresponding source-drain structures (e.g., multiple fins). Logic circuits that process any desired number of inputs may be formed based on the available resources of cell 12 (e.g., how many gate structures are available and how many fins are provided for each gate structure).

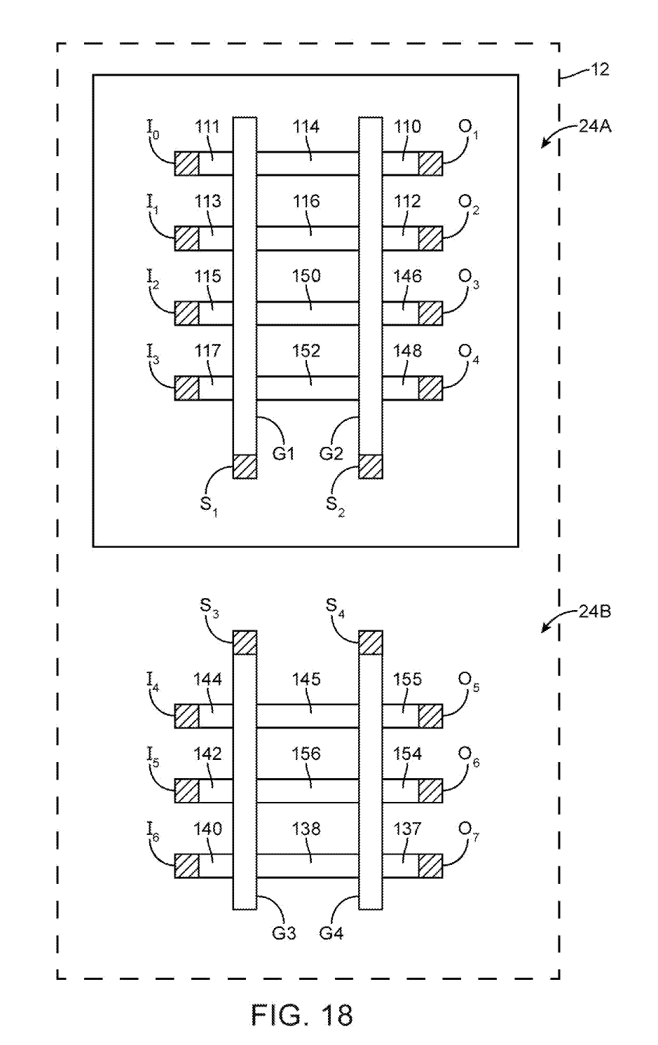

In some arrangements, source-drain structures may receive input signals. FIG. 18 is an illustrative diagram in which cell 12 is metal-programmed to serve as a signal bus that can be controlled to pass multiple input signals to output terminals. As shown in FIG. 18, bus input signals I0, I1, I2, I3, I4, I5, and I6 may be provided to source-drain structures 111, 113, 115, 117, 144, 142, and 140 via metal layer paths coupled to the source-drain structures. Corresponding bus output signals O0, O1, O2, O3, O4, O5, and O6 may be provided at source-drain structures 110, 112, 146, 148, 155, 154, and 137 via metal layer paths coupled to the source-drain structures. Bus control signals S1, S2, S3, and S4 may be provided at gate structures G1, G2, G3, and G4.

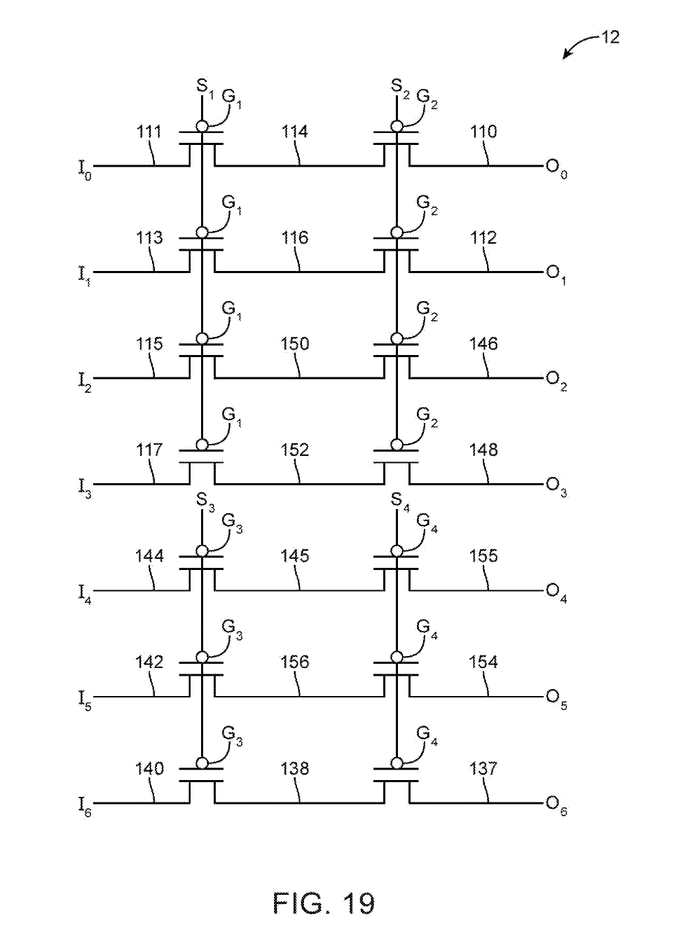

The signal bus arrangement of FIG. 18 may be represented by the circuit diagram of FIG. 19. As shown in FIG. 19, the bus input signals may be passed to the bus outputs when control signals S1 and S2 are logic zero and control signals S3 and S4 are logic one (e.g., because P-type transistors are activated by logic zero gate signals and N-type transistors are activated by logic one gate signals). If desired, gate structures of P-type transistor structures 24A and N-type transistor structures 24B may share input signals. For example, gate structures G1 and G3 may share control signal S1 via a metal layer path that couples structures G1 and G3.

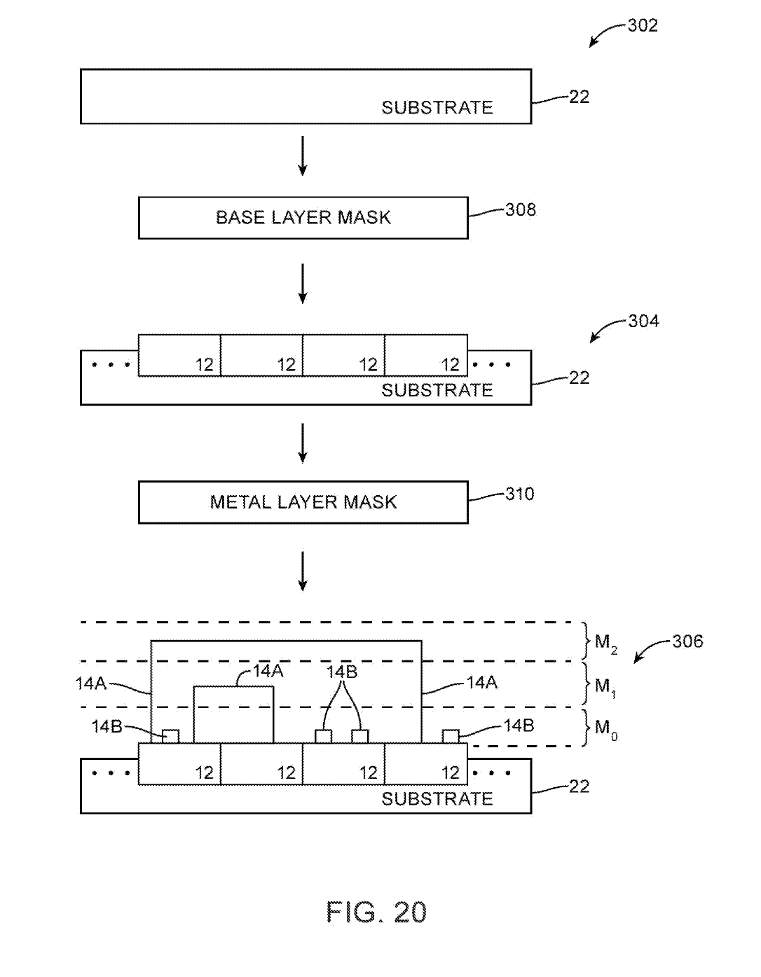

FIG. 20 is an illustrative cross-sectional diagram showing how a metal-programmable integrated circuit such as device 10 of FIG. 10 may be formed and configured (programmed).

During initial step 302, substrate 22 may be provided. During step 304, transistor structures for cells 12 may be formed in substrate 22 using base layer mask 308 (e.g., using lithography and etching operations with the base layer mask). Base layer mask 308 may define an appropriate set of patterns for forming transistor structures such as transistor structures 24 of FIGS. 3-6 or structures 24A. Multi-gate transistor structures such as FinFET transistors may be formed using base layer mask 308. Transistor structures that may be formed with base layer mask 308 may include gate structures, source-drain structures, channel structures, and other transistor structures.

During subsequent step 306, metal layers may be deposited over substrate 22 and the transistor structures of cells 12. In the example of FIG. 20, metal layers M0, M1, and M2 are formed. However, this example is merely illustrative. Any desired number of metal layers may be formed over substrate 22. Metal layer mask 310 may be used to form conductive paths (interconnects) in the metal layers. For example, intra-cell paths 14B and inter-cell paths 14A of FIG. 1 may be formed using metal layer mask 310. The paths formed using metal layer mask 310 may effectively program cells 12 to perform desired circuit functions. For example, some of cells 12 may be metal-programmed as inverters having a desired drive strength (e.g., as shown in FIG. 8, 10, or 12). Other cells 12 may be metal-programmed as multi-input logic gates such as the NAND and NOR gates of FIGS. 14 and 16. Yet other cells 12 may be metal-programmed as signal busses as shown in FIG. 19.

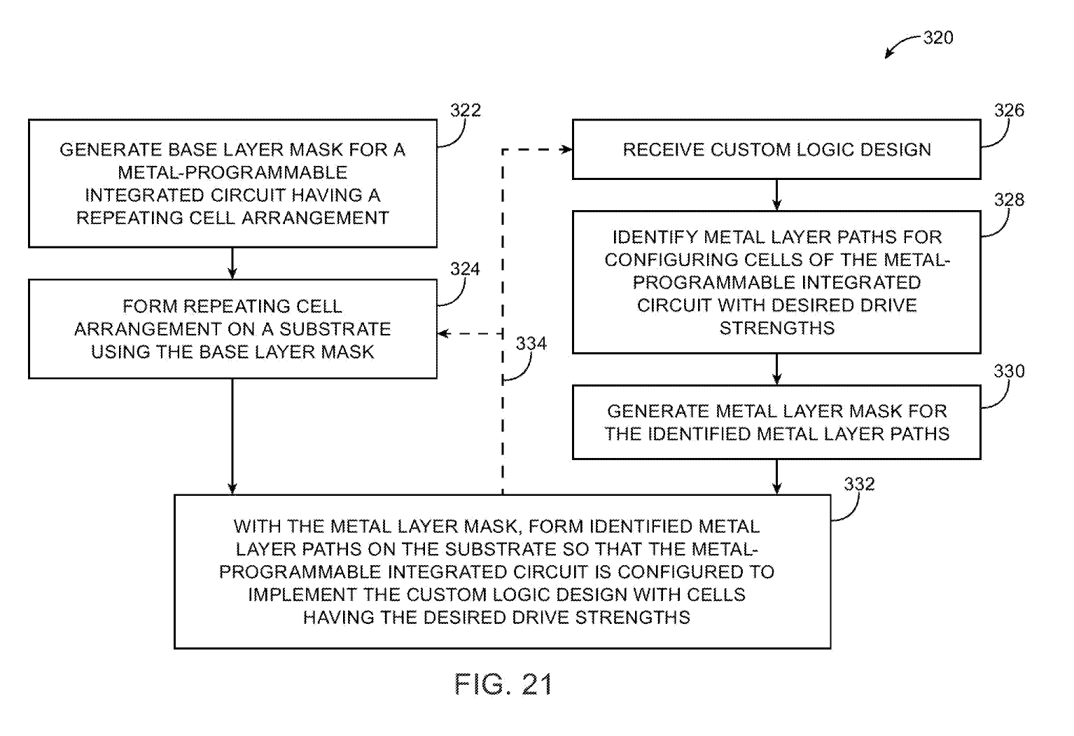

FIG. 21 is a flow chart 320 of illustrative steps that may be performed to manufacture and configure a metal-programmable integrated circuit.

During step 322, a base layer mask may be generated for a metal-programmable integrated circuit. The base layer mask may define a repeating cell arrangement such as an array of cells. Each cell may include transistor structures having metal-programmable configurations. As an example, base layer mask 308 of FIG. 20 may be generated. The transistor structures may include multi-gate transistor structures such as FinFET structures.

During step 324, transistor structures for the repeating cell arrangement of the metal-programmable integrated circuit may be formed on a substrate using the base layer mask (e.g., as shown in step 304 of FIG. 20).

During step 326, a custom logic design may be provided (e.g., by a logic designer). The custom logic design may be received at computing equipment.

During step 328, the computing equipment may identify appropriate metal layer paths for implementing the custom logic design using the cells defined by the base layer mask. The metal layer paths identified may depend on the resources defined for each cell by the base layer mask For example, the metal layer paths identified may depend on how many gate structures, channel structures, source-drain structures are defined per cell. As another example, the metal layer paths identified may depend on the topology of the cells (e.g., which gate structures and source-drain regions are shared within the transistor structures of each cell). The metal layer paths may be used to configure the drive strength of each cell (e.g., by selectively enabling and disabling portions of the transistor structures of each cell).

During step 330, mask-generation equipment may be used to generate a metal layer mask for the identified metal layer paths. The metal layer mask may include patterns corresponding to the identified metal layer paths. If desired, multiple metal layer masks may be generated (e.g., metal layer masks may be generated for each metal layer).

During step 332, the metal layer mask may be used to form the identified metal layer paths in the metal layers over the substrate so that the metal-programmable integrated circuit is configured to implement the custom logic design (e.g., as shown in step 306 of FIG. 20). Each cell may be configured to implement a logic function of the custom logic design and configured to produce output signals with desired drive strength. The operations of flow chart 320 may subsequently return to steps 324 and 326 via optional path 334 to manufacture integrated circuits for different designs using the previously generated base mask by generating additional metal layer masks.

The foregoing is merely illustrative of the principles of this invention and various modifications can be made by those skilled in the art without departing from the scope and spirit of the invention. The foregoing embodiments may be implemented individually or in any combination.

What is claimed is:

1. An integrated circuit comprising:
an array of metal-programmable cells, wherein each cell of the array of metal-programmable cells comprises:
a gate structure; and
a plurality of channel structures that are at least partially enclosed by the gate structure.

2. The integrated circuit defined in claim 1 wherein each cell of the array of metal-programmable cells further comprises:
a plurality of source-drain structures that are coupled to the plurality of channel structures.

3. The integrated circuit defined in claim 2 further comprising:
a substrate, wherein the array of metal-programmable cells are formed in the substrate; and
at least one metal interconnect layer covering the substrate.

4. The integrated circuit defined in claim 3 wherein the array of metal-programmable cells comprises at least first and second metal-programmable cells, the integrated circuit further comprising:
a first set of paths in the metal interconnect layer that configure the first metal-programmable cell to perform a first logic function; and
a second set of paths in the metal interconnect layer that configure the second metal-programmable cell to perform a second logic function.

5. The integrated circuit defined in claim 4 wherein the first set of paths in the metal layer configures the first metal-programmable cell as a first inverter having a first output drive strength and wherein the second set of paths in the metal layer configures the second metal-programmable cell as a second inverter having a second output drive strength that is different from the first output drive strength.

6. The integrated circuit defined in claim 4 wherein the first logic function comprises a logic NAND function.

7. The integrated circuit defined in claim 4 wherein the gate structure of each cell of the array of metal-programmable cells comprises a first gate structure, wherein the plurality of channel structures comprises a first set of channel structures, wherein the plurality of source-drain structures comprises first and second sets of source-drain structures, and wherein each cell of the array of metal-programmable cells further comprises:
a second gate structure;
a second set of channel structures that are at least partially enclosed by the second gate structure; and
a third set of source-drain structures coupled to the second set of channel structures, wherein the second set of source-drain structures are coupled to the second set of channel structures and the first set of channel structures.

8. The integrated circuit defined in claim 4 wherein the gate structure, plurality of channel structures, and the plurality of source-drain structures form a P-type transistor structure.

9. The integrated circuit defined in claim 8 wherein each cell of the array of metal-programmable cells further comprises:
an N-type transistor structure comprising:
an additional gate structure;
an additional plurality of channel structures that are at least partially enclosed by the additional gate structure; and
an additional plurality of source-drain structures that are coupled to the additional plurality of channel structures.

10. The integrated circuit defined in claim 9, wherein the first set of paths is electrically coupled to only a subset of the source-drain regions of the first metal-programmable cell.

11. The integrated circuit defined in claim 10 wherein the first set of paths electrically couples the P-type transistor structure to the N-type transistor structure.

12. The integrated circuit defined in claim 4 wherein the at least one metal layer covering the substrate comprises first and second metal layers covering the substrate and wherein the first and second sets of paths are formed in the first and second metal layers.

13. A method of manufacturing a metal-programmable integrated circuit having a substrate, the method comprising:
with a base layer mask, forming an array of metal-programmable cells in the substrate, wherein each metal-programmable cell includes a gate structure and multiple pairs of source-drain regions coupled to the gate structure.

14. The method defined in claim 13 wherein forming the array of metal-programmable cells in the substrate comprises:
with the base layer mask, forming a plurality of channel structures for each metal-programmable cell, wherein each channel structure extends through the gate structure of that metal-programmable cell between a respective pair of source-drain regions.

15. The method defined in claim 14 wherein each metal-programmable cell comprises a FinFET transistor and wherein forming the plurality of channel structures comprises forming a plurality of fins for the FinFET transistor.

16. The method defined in claim 15 further comprising:
generating a metal layer mask based on a custom logic design; and
with the metal layer mask, forming the plurality of paths in at least one metal interconnect layer that covers the substrate, wherein the plurality of paths configure the metal-programmable cells of the array to perform logic functions of the custom logic design.

17. The method defined in claim 16 wherein forming the plurality of paths comprises:
forming the plurality of paths so that at least some of the metal-programmable cells are configured with different output drive strengths.

18. The method defined in claim 17 wherein forming the plurality of paths so that at least some of the metal-programmable cells are configured with the different output drive strengths comprises:
forming a first set of paths coupled to a first subset of the source-drain regions of a first metal-programmable cell of the array, wherein the first set of paths configures the first metal-programmable cell to perform a first logic function; and
forming a second set of paths coupled to a second subset of the source-drain regions of a second metal-programmable cell of the array, wherein the second set of paths configures the second metal-programmable cell to perform a second logic function, and wherein the first subset is greater than the second subset.

19. An integrated circuit comprising:
a plurality of metal-programmable cells, wherein at least one metal-programmable cell of the plurality of metal-programmable cells comprises:
a multi-gate transistor structure.

20. The integrated circuit defined in claim 19 wherein the multi-gate transistor structure comprises a P-type multi-gate transistor structure and wherein the at least one metal-programmable cell of the plurality of metal-programmable cells further comprises an N-type multi-gate transistor structure.

21. The integrated circuit defined in claim 20 wherein the P-type multi-gate transistor structure comprises a P-type FinFET transistor having a first plurality of fins associated with a first gate structure and wherein the N-type multi-gate transistor structure comprises an N-type FinFET transistor having a second plurality of fins associated with a second gate structure.

22. The integrated circuit defined in claim 21 wherein the P-type FinFET transistor includes a third gate structure associated with the first plurality of fins and wherein the N-type FinFET transistor includes a fourth gate structure associated with the second plurality of fins.

23. The integrated circuit defined in claim 22 further comprising:
a substrate in which the plurality of metal-programmable cells are formed;
at least one metal layer covering the substrate; and
a set of paths that is coupled to a subset of the first and second plurality of fins, wherein the set of paths configures the P-type and N-type FinFET transistors to perform a logic function.
